(19) United States
(12) Patent Application Publication
(10) Pub. No.: US 2026/0036628 A1
(43) Pub. Date: Feb. 5, 2026

(54) TESTING AN INSULATION OF A CONDUCTOR SEGMENT FOR AN ELECTRICAL MACHINE, PROVIDING CONDUCTOR SEGMENTS WITH A TEST, AND TEST DEVICE FOR PERFORMING THE TEST

(71) Applicant: GROB-WERKE GmbH & Co. KG, MINDELHEIM (DE)

(72) Inventors: Markus GREINER, KIRCHHEIM (DE); Patrick WIMBAUER, MEMMINGEN (DE); Michael SINNER, BAD GRÖNENBACH (DE)

(21) Appl. No.: 19/285,447

(22) Filed: Jul. 30, 2025

(30) Foreign Application Priority Data
Aug. 1, 2024 (EP) 24192440.6

(51) Int. Cl. G01R 31/34

(52) U.S. Cl. CPC G01R 31/346

(57) ABSTRACT

A method for testing an insulation of a conductor segment for an electrical machine for defects by: a) electrically connecting a conductor segment connection of the conductor segment to a test connection; b) capacitive charging of the conductor segment; c) relatively moving the conductor segment and a test contact in order to scan the area to be tested of the insulation with the test contact, and d) checking whether an electrical connection exists between the test connection and the test contact during step c) in order to conclude that there is a defect in the insulation. Step b) occurs before or during step c). Also a device for performing such a test method.

### CROSS-REFERENCES TO RELATED APPLICATIONS

This application claims the benefit of European Patent Application Number 24 192 440.6 filed on Aug. 1, 2024, the entire disclosure of which is incorporated herein by way of reference.

### FIELD OF THE INVENTION

The invention relates to a method for testing an insulation of a conductor segment for an electrical machine for defects. The invention further relates to a method for providing conductor segments for the manufacture of hairpin stators in large-scale industrial manufacture, the method comprising performing such a test method. The invention further relates to a test device for testing an insulation of a conductor segment for an electrical machine for defects.

The invention resides in the field of manufacturing electrical machines, especially large-scale industrial manufacture of stators such as hairpin stators or wave winding stators. Embodiments of the invention relate to a method and a device for quality assurance in the course of providing conductor segments for electrical machines. In particular, embodiments of the invention are used in the field of assembly machines for assembling electrical machines such as electric motors.

### BACKGROUND OF THE INVENTION

For the technological background, reference is first made to the following literature, which is incorporated herein by reference and which discloses methods and devices used in the industrial large-scale manufacture of hairpin stators:
[1] DE 10 2018 103 926 A1
[2] DE 10 2018 102 914 A1
[3] DE 10 2018 106 980 A1
[4] DE 10 2018 106 978 A1
[5] DE 10 2018 108 656 A1
[6] WO 2019/161832 A1
[7] DE 10 2018 117 A1
[8] DE 10 2018 106 977 A1
[9] WO 2019/161846 A1
[10] WO 2018/233769 A1
[11] DE 10 2018 112 876 A1
[12] WO 2018/233771 A1
[13] EP 3 771 079 A1
[14] EP 3 771 078 A1
[15] EP3763472B1
[16] EP 3 797 918 A1
[17] WO 2021/160414 A1
[18] EP 3 905 494 A1
[19] WO 2022/096079 A1
[20] EP 4 239 898
[21] Wikipedia “Hairpin technology,” downloaded on May 23, 2024, from https://en.wikipedia.org/wiki/Hairpin_technology
[22] VDMA, Manufacture Process of Hairpin stators, downloaded on May 23, 2024, from https://www.researchgate.net/publication/337363214_Produktionsprozess_eines_Hairpin stators
[23]U.S. Pat. No. 11,018,482 B2.

Reference is also made to the following literature concerning the industrial large-scale manufacture of wave winding stators, which is also incorporated herein by reference:
[24] WO 2019/020148 A1
[25] WO 2020/187363 A1
[26] WO 2019/166060 A1
[27] WO 2019/166061 A1
[28] WO 2017/102892 A2
[29] DE 10 2020 130 647 A1
[30] EP 3 886 303 A1
[31] GB 1 027 777 A
[32] GB 639 069 A
[33] WO 2018/019970A1
[34] DE 10 2020 117 771 A1
[35] DE 10 2021 134 599 A1
[36] DE 10 2020 130 647 A1
[37] DE 10 2018 108 615 A1
[38] DE 10 2018 103 926 A1.

Electrical machines are understood to be, in particular, machines for converting electrical energy into kinetic energy and machines for converting kinetic energy into electrical energy. In particular, these are understood to be electric motors and generators. The invention concerns methods and devices used in the context with large-scale industrial manufacture of stators or similar components for such electrical machines that are intended to be used as electric motors for electrically powered vehicles. More specifically, some embodiments of the invention concern methods and devices for use in the manufacture of hairpin stators or, in other words, in the manufacture of stators using the so-called hairpin technology, as explained in particular in references [21] or [22]. In this process, individual conductor sections are first provided, shaped in a U-shape or hairpin shape—these bent conductor sections are also called hairpins or simply pins—and inserted into a laminated core of a stator either individually or combined into rings, so that the U-bends (called winding heads) lie on one axial side and the conductor ends protrude on the other side. To form the coil winding, the protruding conductor ends are bent and clamped together to form pairs and are welded together. However, the methods and devices according to embodiments of the invention can also be used in the manufacture, in particular large-scale manufacture, of wave winding stators, as described and shown in more detail in references [24] to [38].

In both hairpin technology and wave winding technology, conductor segments, in particular wire segments, for example made of copper, preferably with a rectangular cross-section with insulation, are provided for the manufacture of coil windings of electrical machine components. In particular, for this purpose, an endless conductor with an electrical insulation layer on the outside—in particular a polymer insulation layer—is unwound from a roll. Conductor segments separated from the endless conductor are bent into the desired shape to produce the coil winding.

Although the bending operating is carried out as gently as possible, damage to the insulation may occur, especially after bending. If conductor segments with defective insulation are installed in a component, this may lead to a rejected component under certain circumstances. It is therefore advantageous to check the insulation of the conductor segments for damage before installation.

A test method and a test device for testing the insulation of such conductor segments are known from the following literature:
[39] YouTube video “HVC 360 SA In-Line tester for hairpins,” downloaded on Jul. 23, 2024, from https://youtu.be/nVd308TaPzs
[40] DSE Test Solutions website, downloaded on Jul. 23, 2024, from https://dsetestsolutions.com/e-vehicle-hair-pin

### SUMMARY OF THE INVENTION

The invention is based on the problem of enabling improved testing of an insulation of conductor segments for electrical machines in terms of large-scale industrial manufacture.

To solve this problem, the invention creates a test method according to one or more embodiments described herein. A supply method for providing conductor segments while performing such a test method and a test device, in particular for performing such a test method, are also described herein.

The invention provides a method for testing an insulation of a conductor segment for an electrical machine for defects, comprising:
a) electrically connecting a conductor segment connection of the conductor segment to a test connection,
c) relatively moving the conductor segment and a test contact in order to scan the area to be tested of the insulation with the test contact, and
d) checking whether an electrical connection exists between the test connection and the test contact during step c) in order to detect a defect in the insulation.

According to the invention, the method further comprises the step to be performed before or during step c):
b) capacitively charging the conductor segment.

In some embodiments, step b) comprises the step:
b1) applying an electrical field ahead of the test contact in the direction of movement.

In some embodiments, step b) comprises the step:
b2) providing a potential equalization element arranged ahead of the test contact in the relative direction of movement and applying a voltage for capacitive charging between the potential equalization element and the test connection.

In some embodiments, it is provided that in step b2), a potential equalization contact is provided as the potential equalization element for contacting the conductor segment, and that step b) further comprises the step:
b3) scanning the area to be tested of the insulation with the potential equalization contact.

In some embodiments, it is provided that the voltage for capacitive charging is higher than a test voltage applied in step d) to test the electrical connection between the test connection and the test contact.

Some embodiments of the test method further comprise the step of providing a contact element similar to the test contact as a potential equalization contact.

Some embodiments of the test method further comprise the step of providing at least one contact brush as a test contact and/or as a potential equalization contact.

Some embodiments of the test method further include the step:
providing an elongated test contact and/or an elongated potential equalization contact in an arrangement inclined obliquely relative to the direction of movement.

Some embodiments of the test method further comprise the step:
providing the test contact and/or the potential equalization contact with electrically conductive fibers, such as carbon fibers in particular.

Some embodiments of the test method further comprise the step:
relatively moving the conductor segment connected to the test connection relative to a holder which is designed in particular as a housing, on which holder the potential equalization contact is arranged first and then the test contact, as viewed in the direction of movement.

In some embodiments, the insulation of a hairpin conductor or an I-pin conductor for a hairpin stator of an electrical machine is tested.

In some embodiments, the insulation of a wave winding conductor for forming a wave winding mat is tested.

In some embodiments, the insulation of a wave winding mat is tested.

According to a further aspect, the invention relates to a method (supply method) for providing conductor segments for manufacturing hairpin stators in large-scale industrial manufacture, the method comprising performing a test method according to one or more of the preceding configurations after bending the conductor segments.

According to a further aspect, the invention relates to a test device for testing the insulation of a conductor segment for an electrical machine for defects, the device comprising:
a test connection for electrical connection to a conductor segment connection of the conductor segment,
a test contact for scanning the area to be tested of the insulation;
a relative movement device for relatively moving the conductor segment connected to the test connection and the test contact in order to scan the area to be tested of the insulation with the test contact,
a checking device which is designed to check whether an electrical connection exists between the test connection and the test contact during the scanning of the insulation with the test contact, in order to detect a defect in the insulation, and
a charging device for capacitively charging the conductor segment before or during the scanning with the test contact.

In some embodiments of the test device, it is provided that the charging device is designed to apply an electric field ahead of the test contact in the direction of movement.

In some embodiments of the test device, it is provided that the charging device comprises a potential equalization element arranged ahead of the test contact in the relative direction of movement and configured to apply a voltage for capacitive charging between the potential equalization element and the test connection.

In some embodiments of the test device, it is provided that the potential equalization element has a potential equalization contact for contacting the conductor segment, and the test device is designed to first scan the area to be tested of the insulation with the potential equalization contact and with the test contact, wherein, in particular, the potential equalization contact is arranged to be leading with respect to the test contact.

In some embodiments of the test device, it is provided that the test device is designed to apply a voltage for capacitive charging between the potential equalization element and the test connection which is higher than a test voltage applied to test the electrical connection between the test connection and the test contact.

In some embodiments of the test device, it is provided that the potential equalization contact is of the same type as the test contact.

In some embodiments of the test device, it is provided that the test contact and/or the potential equalization contact each have at least one contact brush.

In some embodiments of the test device, it is provided that the test contact and/or the potential equalization contact are elongated and arranged inclined obliquely relative to the direction of movement.

In some embodiments of the test device, it is provided that the test contact and/or the potential equalization contact have electrically conductive carbon fibers.

In some embodiments of the test device, it is provided that a holder is provided, in particular in the form of a housing, on which holder the potential equalization contact is arranged first and then the test contact, viewed in the relative direction of movement.

Some embodiments of the test device comprise a computer-implemented control unit. In particular, with the aid of the computer-implemented control unit, the test device is set up to carry out the test procedure according to a previously described configuration. In some embodiments, the computer-implemented control unit includes a processor and a memory. In particular, a computer program with control instructions is loaded into the memory, which instructions cause the test device to perform the test procedure according to any of the above configurations.

Embodiments of the invention relate to an inline conductor segment insulation test. In particular, the insulation can be tested inline during the large-scale manufacture of a coil winding of an electrical machine. In some embodiments, in particular hairpins or I-pins or also other conductor segments for forming coil windings, such as wave winding wires or also conductor segment arrangements already formed from several conductor segments, such as winding mats, can be tested for defects in the insulation.

Some advantages of preferred embodiments of the invention are explained in more detail below.

In previously known test methods for testing the insulation of conductor segments for defects, the maximum speed at which reliable detection of defects can still be guaranteed is severely limited due to the operating principle. For example, in the test known from [39] and [40], a maximum production line speed for hairpins and I-pins of 500 mm/s at a test voltage of 1500 V and a threshold value of 24 μA is specified.

Embodiments of the invention, on the other hand, offer a possibility for reliable testing/detection at higher speeds. This allows shorter cycle times to be achieved in the manufacture of electric motors.

In particular, in embodiments of the invention, the maximum speed at which reliable detection of defects can still be guaranteed is no longer limited.

This allows the insulation to be safely tested inline during large-scale manufacture of coil windings for electrical machines even at higher speeds. This improves testing, particularly with regard to safety, even at faster production speeds.

### BRIEF DESCRIPTION OF THE DRAWINGS

An embodiment of the invention is explained in more detail below with reference to the accompanying drawings.

FIG. 1 is a schematic side view of a test device according to a comparative example at a first stage of a test method for testing the insulation of a conductor segment for manufacturing a coil winding of an electrical machine, according to a comparative example;

FIG. 2 is a further schematic side view of the test device according to the comparative example at a further stage of the test method according to the comparative example;

FIG. 3 is a view comparable to FIG. 2 of a test device according to an embodiment of the invention at a stage of a test method according to an embodiment of the invention; and

FIG. 4 is a view comparable to FIG. 3, where the test device is shown during the execution of a test procedure according to a further embodiment of the invention with a different shape of the conductor segment.

### DETAILED DESCRIPTION OF THE PREFERRED EMBODIMENTS

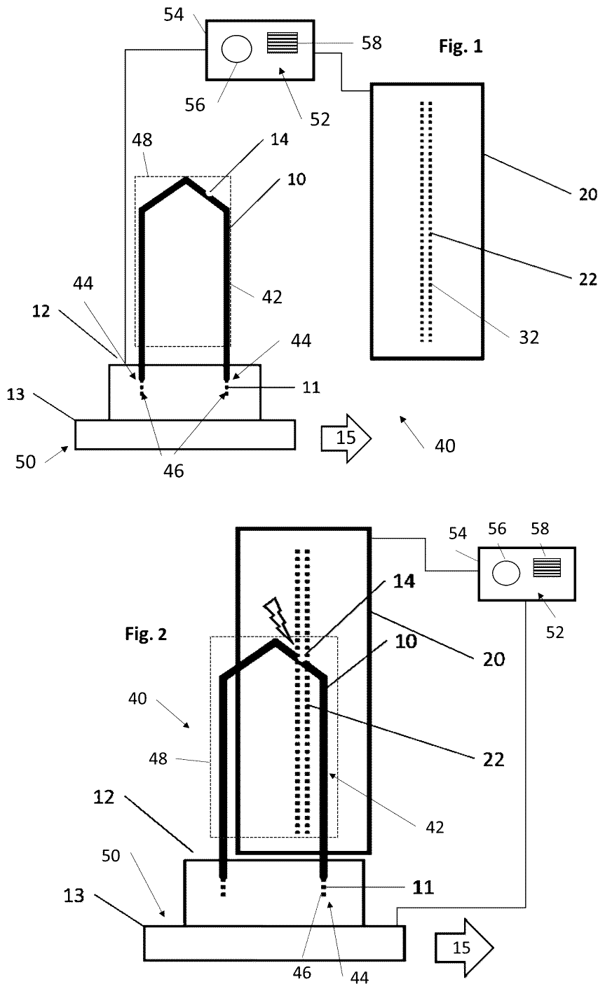

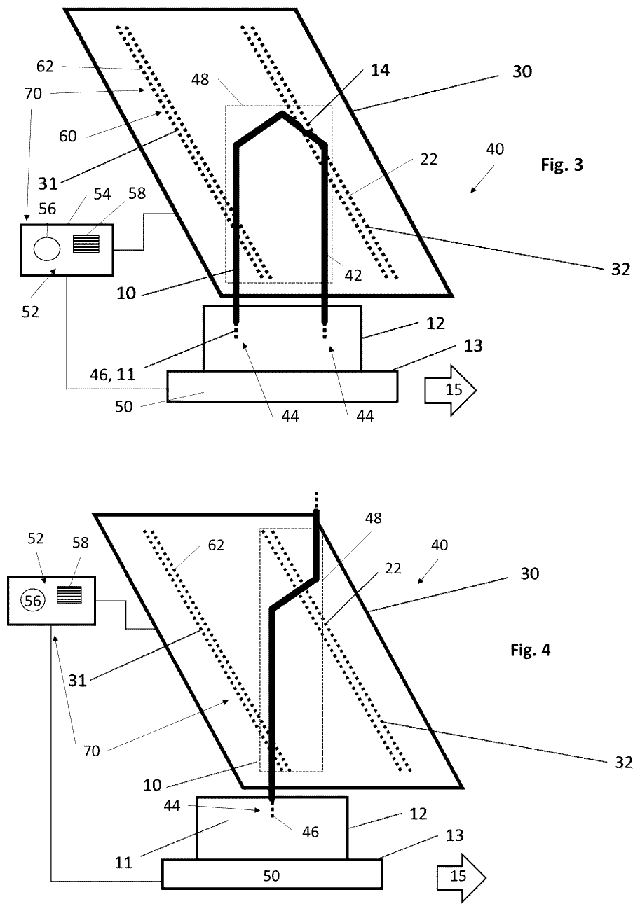

The Figures each show a test device 40 for testing an insulation 42 of a conductor segment 10 for an electrical machine for defects 14 when performing a test procedure for testing the insulation of the conductor segment 10 for defects 14, wherein FIGS. 1 and 2 each show a test device 40 and a test method according to a comparative example not covered by the invention, similar to the prior art according to [39] or [40], and FIGS. 3 and 4 show embodiments of the test device 40 and of the test method according to the invention. In each case, corresponding features are illustrated using the same reference signs.

The test device 40 is designed to test an insulation 42 of a conductor segment 10 for an electrical machine for defects 14. The test device 40 has a test connection 44 for electrical connection to a conductor segment connection 46 of the conductor segment 10, a test contact 32 for scanning the area 48 to be tested of the insulation 42, a relative movement device 50 for relatively moving the conductor segment 10 connected to the test connection 44 and the test contact 32, in order to scan the area 48 to be tested of the insulation 42 with the test contact 32, and a checking device 52 which is designed to check whether an electrical connection exists between the test connection 44 and the test contact 32 during the scanning of the insulation 42 by the test contact 32, in order to detect a defect in the insulation.

The test device 40 is, for example, part of a manufacturing plant (not shown) for manufacturing a component of an electrical machine, such as a stator for electric vehicle drive motors, in large-scale industrial manufacture. The test device 40 is in particular part of a supply device, which is not shown but is known from the prior art mentioned at the beginning according to [1] to [37], for providing preformed conductor segments 10, such as in particular already bent hairpins of hairpin stators. For example, the test device 40 is arranged in a region between a bending station for bending the conductor segments 10 and a coil winding manufacturing station, where a coil winding is formed from the conductor segments 10.

The conductor segment connection 46 is designed according to the conductor segment 10 to be tested; for example, the conductor segment connection 46 has an uninsulated end 11 of the conductor segment 10.

The test connection 44 can be designed differently, provided that it performs the function of a suitable electrical connection to the conductor segment connection 46. For example, the test connection 44 can have one or more sockets into which a respective uninsulated end 11 of the conductor segment 10 is inserted, or another suitable contact. In some embodiments, the respective conductor segment 10 is gripped by a gripper 12 on a transport device 13 during transport from the bending station or similar supply device to a further processing station, wherein during gripping, an electrical contact, e.g., on at least one gripping jaw of the gripper 12, is brought into engagement with the uninsulated end 11.

The test contact 32 can also be designed differently, provided that it can perform the function of scanning the area to be tested. Advantageously, the test contact 32 has electrically conductive fibers, in particular carbon fibers. In particular, the test contact 32 has a contact brush 22 with one or more rows of fiber tufts.

The relative movement device 50 can also be designed differently, provided that relative movement in the relative movement direction 15 between the conductor segment 10 and the test contact 32 takes place in order to scan the area 48 to be tested. In some embodiments not shown, the test contact 32 is of movable design. In the examples shown, the relative movement device 50 is designed to move the conductor segment 10. For example, the relative movement device 50 has the transport device 13, by means of which the conductor segments 10 on transport units, for example grippers 12, are moved past the test contact 32, with the conductor segment connection 46 being connected to the test connection 44.

For example, the test contact 32 is arranged on or in a housing 20, 30, through which the conductor segments 10 are transported.

The checking device 52 includes means for generating a voltage between the test contact 32 and the test connection 44 and means for detecting a current between the test contact 32 and the test connection 44. For example, a direct voltage in the range from 350 V to 6000 V is applied. The checking device 52 further comprises an evaluation device which is designed to detect a defect 14 when a current is detected and to output a signal for rejecting the corresponding conductor segment 10. The checking device 52 is in particular computer-implemented and can be designed as a separate unit or, as shown, as part of a computer-implemented control unit 54 for controlling the test device 40. The control unit 54 has a processor 56 and a memory 58 with a computer program loaded therein, which causes the test device 40 to automatically carry out the test procedure described in more detail below.

To test the insulation 42 of the conductor segment 10 for an electrical machine for defects 14, a method is carried out with the following steps:
a) electrically connecting the conductor segment connection 46 of the conductor segment 10 to the test connection 44,
c) relatively moving the conductor segment 10 and the test contact 32 in order to scan the area 48 to be tested of the insulation 42 with the test contact 32, and
d) checking whether an electrical connection exists between the test connection 44 and the test contact 32 during step c) in order to detect a defect 14 in the insulation 42.

In the comparative example shown in FIGS. 1 and 2, a single contact brush 22 is provided in the housing 20 to form the test contact, wherein the contact brush 22 is arranged perpendicular to the relative direction of movement 15. For example, a voltage of 1500 V is applied. This allows a defect 14 to be detected relatively well at lower relative movement speeds. However, the maximum speed at which reliable detection of defects can still be guaranteed is quite limited, so that testing can only take place at relatively low clock speeds.

Studies have shown that false detections occur at higher speeds with the test method according to the comparative example. An isolated conductor segment 10 behaves capacitively. When voltage is applied, a high current flows under rapid change in speed of the conductor segment 10 relative to the contact brush 22/test contact 32 (capacitive behavior->current is leading), which would lead to false detection of a defect even though there is no damage to the insulation.

In the embodiments of the invention shown in FIGS. 3 and 4 and explained below, the maximum speed at which reliable detection of defects 14 is still guaranteed is no longer limited. Thus, embodiments of the invention offer possibilities for reliable testing/detection at higher speeds, so that shorter cycle times can be achieved in the manufacture of electric motors.

For this purpose, embodiments of the test method according to the invention additionally include the step to be performed before or during step c):
b) capacitive charging of the conductor segment 10.

In some embodiments, an electric field is applied ahead of the test contact 32 in the direction of movement 15.

The test device 40 according to embodiments of the invention comprises a charging device 70 for capacitive charging of the conductor segment 10 before or during scanning by the test contact 32 in order to carry out the test method. The charging device 70 is designed in particular to apply an electric field to the conductor segment 10 ahead of the test contact 32 in the direction of movement 15.

The test device 40 according to embodiments of the invention shown in FIGS. 3 and 4 provides a potential equalization element 60 for this purpose, which is preferably arranged ahead of the test contact 32 in the direction of movement 15. The potential equalization element 60 can be designed differently, provided that it is suitable for applying the electric field for capacitive charging. It can, for example, be designed in the form of a plate or as a conductor track. In the embodiments shown, the potential equalization element 60 is designed in the same way as the test contact 32. For example, the potential equalization element 60 has a further contact 31 for potential equalization—referred to below as potential equalization contact 31—which is designed in particular as a further contact brush 62. The potential equalization contact 31 is arranged for example in the housing 30 ahead of the test contact 32 in the direction of movement 15.

For capacitive charging, a voltage is applied between the potential equalization element 60 and the test connection 44.

In the embodiments shown, the two contacts 31 (potential equalization contact) and 32 (test contact) are arranged in such a way that, for the different geometries of the conductor segments 10 to be tested, a state exists when passing through the housing 30, during which the conductor segment 10 is simultaneously in connection with both contacts 31 and 32.

The conductor segment 10 is moved into the housing 30 in a contacted state—uninsulated conductor end 11 in contact with test connection 44, e.g., on the gripper 12—with the transport—transport device 13. The housing 30 is designed in such a way that when the conductor segment 10 is moved in, capacitive charging occurs—e.g., at the potential equalization contact 31—in order to avoid faulty detection due to the capacitive behavior of the system. In a further position, the test contact 32 is mounted, which detects a fault/defect in the insulation 14.

In order to maintain the electric field, in the embodiments shown, the conductor segment 10 for detecting a defect 14 when entering the test contact 32 is still connected to the potential equalization contact 31.

In some embodiments, the test contact 32 and the potential equalization contact 31 are elongated and inclined obliquely relative to the direction of movement 15.

Detection of defects 14 in the insulation 42 in independent conductor segments 10 is possible for all possible conductor segment geometries independent of speed and can therefore be carried out in the machine (manufacturing system) cycle time-neutral. This is because the capacitive charging, which leads to false detections at high speeds when only one test contact 32 is used, as in the comparative example, is already anticipated by a preceding charging, in particular by a preceding contacting (e.g., with the potential equalization contact 31) and therefore no significant capacitive charging occurs when the test contact 32 is contacted.

A slightly increased voltage (e.g. 2000 V) is preferably applied to the potential equalization contact 31, so that during the time until the test contact 32 is reached, a potential equalization at its level has already been achieved (e.g. 1500 V). A direct voltage is applied.

The contact brushes 22, 62 are preferably made of electrically conductive carbon fibers. However, other electrically conductive fibers/brush hairs are also conceivable.

The contact brushes 22, 62 are preferably arranged in an arrow shape in the direction of travel—direction of movement 15—due to better contacting and longer service life.

The rear points of the conductor segment 10 in the direction of movement 15 are reliably detected by the arrow-shaped arrangement in the direction of travel, by the inherent rigidity of the fibers, and by the fact that, due to the high voltage, defects 14 also cause an electrical breakdown at a certain distance from the detecting brush.

FIG. 3 shows the test procedure for testing a conductor segment 10 designed as a hairpin (U-shaped conductor). As can be seen in FIG. 4, other conductor segment shapes can also be tested, such as I-pins or wave-shaped conductor segments (for wave windings). The test principle can therefore also be used to test other conductor geometries reliably and with a high cycle time.

Although the Figures only show one side of the respective housing 20, 30 with a contact brush 22, 62 for scanning one side of the conductor segment 10, it should be clear that the brushes of the contact brushes can be directed toward the conductor segment 10 from opposite sides in order to scan the entire surface of the area 48 to be tested of the conductor segment.

The invention relates to a method for testing an insulation (42) of a conductor segment (10) for an electrical machine for defects, comprising:
a) electrically connecting a conductor segment connection (46) of the conductor segment (10) to a test connection (44),
c) relatively moving the conductor segment (10) and a test contact (32) to scan the area (48) of the insulation (42) to be tested with the test contact (32), and
d) checking whether an electrical connection exists between the test terminal (44) and the test contact (32) during step c) in order to conclude that there is a defect (14) in the insulation (42).

In order to reliably detect defects (14) even at higher speeds and to reduce or avoid false detections, the method further comprises the step to be performed before or during step c):
b) (targeted) capacitive charging of the conductor segment (10).

The systems and devices described herein may include a controller or a computing device comprising a processing unit and a memory which has stored therein computer-executable instructions for implementing the processes described herein. The processing unit may comprise any suitable devices configured to cause a series of steps to be performed so as to implement the method such that instructions, when executed by the computing device or other programmable apparatus, may cause the functions/acts/steps specified in the methods described herein to be executed. The processing unit may comprise, for example, any type of general-purpose microprocessor or microcontroller, a digital signal processing (DSP) processor, a central processing unit (CPU), an integrated circuit, a field programmable gate array (FPGA), a reconfigurable processor, other suitably programmed or programmable logic circuits, or any combination thereof.

The memory may be any suitable known or other machine-readable storage medium. The memory may comprise non-transitory computer readable storage medium such as, for example, but not limited to, an electronic, magnetic, optical, electromagnetic, infrared, or semiconductor system, apparatus, or device, or any suitable combination of the foregoing. The memory may include a suitable combination of any type of computer memory that is located either internally or externally to the device such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like. The memory may comprise any storage means (e.g., devices) suitable for retrievably storing the computer-executable instructions executable by processing unit.

The methods and systems described herein may be implemented in a high-level procedural or object-oriented programming or scripting language, or a combination thereof, to communicate with or assist in the operation of the controller or computing device. Alternatively, the methods and systems described herein may be implemented in assembly or machine language. The language may be a compiled or interpreted language. Program code for implementing the methods and systems described herein may be stored on the storage media or the device, for example a ROM, a magnetic disk, an optical disc, a flash drive, or any other suitable storage media or device. The program code may be readable by a general or special-purpose programmable computer for configuring and operating the computer when the storage media or device is read by the computer to perform the procedures described herein.

Computer-executable instructions may be in many forms, including modules, executed by one or more computers or other devices. Generally, modules include routines, programs, objects, components, data structures, etc., that perform particular tasks or implement particular abstract data types. Typically, the functionality of the modules may be combined or distributed as desired in various embodiments.

It will be appreciated that the systems and devices and components thereof may utilize communication through any of various network protocols such as TCP/IP, Ethernet, FTP, HTTP and the like, and/or through various wireless communication technologies such as GSM, CDMA, Wi-Fi, and WiMAX, is and the various computing devices described herein may be configured to communicate using any of these network protocols or technologies.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

### LIST OF REFERENCE SIGNS

10 conductor segment
11 uninsulated end of the conductor segment
12 gripper and/or contact
13 transport device
14 defect, e.g. fault, in insulation
15 relative direction of movement
20 housing for contact brush or similar (test contact)
22 individual contact brush
25 housing for contact brush or similar
31 potential equalization contact
32 test contact
40 test device
42 insulation
44 test connection
46 conductor segment connection
48 area to be tested
50 relative movement device
52 checking device
54 control unit
56 processor
58 memory
60 potential equalization element
62 contact brush
70 charging device

1. A method for testing an insulation of a conductor segment for an electrical machine for defects, the method comprising:
a) electrically connecting a conductor segment connection of a conductor segment to a test connection;
b) capacitively charging the conductor segment;
c) relatively moving the conductor segment and a test contact in order to scan a to-be-tested area of the insulation with the test contact; and
d) checking whether an electrical connection exists between the test connection and the test contact during step c) in order to determined when that there is a defect in the insulation,
wherein step b) is performed before or during step c).

2. The method according to claim 1, wherein step b) comprises:
b1) applying an electric field ahead of the test contact in a direction of movement.

3. The method according to claim 1, wherein step b) comprises:
b2) providing a potential equalization element arranged ahead of the test contact in a direction of movement and applying a voltage for capacitive charging between the potential equalization element and the test connection.

4. The method according to claim 3, wherein in step b2), a potential equalization contact is provided as the potential equalization element for contacting the conductor segment, and step b) further comprises the step:
b3) scanning the to-be-tested area of the insulation with the potential equalization contact.

5. The method according to claim 3, wherein the voltage for capacitive charging is higher than a test voltage applied in step d) to test the electrical connection between the test connection and the test contact.

6. The method according to claim 3, further comprising at least one of the following steps:
providing a contact element as a potential equalization contact;
providing at least one contact brush as the test contact or as the potential equalization contact or as both;
providing an elongated test contact or an elongated potential equalization contact or both in an arrangement inclined obliquely relative to the direction of movement;
providing the test contact or the potential equalization contact or both with electrically conductive carbon fibers; or
relatively moving the conductor segment connected to the test connection relative to a holder, which comprises a housing and on which the potential equalization contact is arranged first and then the test contact, as viewed in the direction of movement.

7. The method according to claim 1, wherein the insulation of a hairpin conductor or an I-pin conductor for a hairpin stator of an electrical machine is tested, or
wherein the insulation of a wave winding conductor for forming a wave winding mat is tested, or
wherein the insulation of a wave winding mat is tested.

8. A method for providing conductor segments for manufacturing hairpin stators in large-scale industrial manufacture, comprising:
performing the method according to claim 1 after bending the conductor segments.

9. A device for testing an insulation of a conductor segment for an electrical machine for defects, the device comprising:
a test connection for electrical connection to a conductor segment connection of the conductor segment;
a test contact for scanning a to-be-tested area of the insulation;
a relative movement device for moving the conductor segment connected to the test connection and the test contact relative to one another in order to scan the to-be-tested area of the insulation with the test contact;
a checking device configured to check whether an electrical connection exists between the test connection and the test contact during a scanning of the insulation by the test contact in order to determine when there is a defect in the insulation; and,
a charging device for capacitively charging the conductor segment before or during the scanning by the test contact.

10. The device according to claim 9, wherein the charging device is designed to apply an electric field ahead of the test contact in a direction of movement.

11. The device according to claim 9, wherein the charging device has a potential equalization element arranged ahead of the test contact in a direction of movement and is configured to apply a voltage for capacitive charging between the potential equalization element and the test connection.

12. The device according to claim 11, wherein the potential equalization element has a potential equalization contact for contacting the conductor segment,
wherein the device is configured to scan the to-be-tested area of the insulation with the potential equalization contact and with the test contact, and
wherein the potential equalization contact is arranged to be leading with respect to the test contact.

13. The device according to claim 11, wherein test device is configured to apply the voltage for capacitive charging between the potential equalization element and the test connection which is higher than a test voltage applied for testing the electrical connection between the test connection and the test contact.

14. The device according to claim 11, wherein the potential equalization contact is designed in a same way as the test contact, or
wherein the test contact, or the potential equalization contact, or both each have at least one contact brush, or
wherein the test contact, or the potential equalization contact, or both are elongated and arranged inclined obliquely relative to the direction of movement, or
wherein the test contact, or the potential equalization contact, or both have electrically conductive carbon fibers, or
wherein the test device further comprises a holder comprising a housing and on which the potential equalization contact is arranged first and then the test contact, viewed in the direction of movement.

15. The device according to claim 9, further comprising:
a control unit for carrying out a method for testing an insulation of a conductor segment for an electrical machine for defects.
